(19) United States
(12) Patent Application Publication
(10) Pub. No.: US 2006/0017127 A1
(43) Pub. Date: Jan. 26, 2006

(54) Optical package for a semiconductor sensor

(75) Inventor: Emmanuelle Vigier-Blanc, Le Sappey En Chartreuse (FR)

Correspondence Address: STMicroelectronics Inc.;c/o WOLF, GREENFIELD & SACKS, PC, Federal Reserve Plaza, 600 Atlantic Avenue, BOSTON, MA, 02210-2206, US

(73) Assignee: STMicroelectronics, S.A., Montrouge (FR)

(21) Appl. No.: 11/187,634

(22) Filed: Jul. 22, 2005

(30) Foreign Application Priority Data
Jul. 22, 2004 (FR) 04/51618

(51) Int. Cl. H01L 31/0232; H01L 21/00

(52) U.S. Cl. 257/432; 257/433; 438/64

(57) ABSTRACT

An optical package for integrated circuit chips including optical microsensors and its manufacturing method, an encapsulation resin thickness smaller than the thickness provided straight above connecting wires being provided at least straight above the microsensors between the upper surface of the chip and a substrate supporting it.

### BACKGROUND OF THE INVENTION

1. Field of the Invention

The present invention generally relates to optical sensors formed by integrated circuits using semiconductor technology. Such sensors are essentially formed of a network of phototransistors and formed in an integrated circuit chip, assembled on a substrate for packaging with a focusing lens.

The present invention more specifically relates to semiconductor devices with an optical sensor, the focusing lens of which enables avoiding a focus setting.

The present invention more specifically applies to optical sensors intended to form microcameras or optical mice.

2. Discussion of the Related Art

FIGS. 1 and 2 show, respectively in a cross-section view and in a simplified top view, a conventional example of an optical package 10 with semiconductor sensors. An integrated circuit chip 1 in which phototransistors topped with silicon microlenses have been formed is arranged on a substrate 2 in which are formed vias (not shown) of contact transfer between its front surface and its rear surface. The rear surface of substrate 2 (opposite to that supporting chip 1) comprises conductive bosses, like a BGA (ball grid array) package. Conductive wires 22 for connecting the front surface of chip 1 are arranged at the front surface of substrate 2. The assembly is encapsulated in an optical resin 3, overmolded from the front surface of substrate 2. This resin conventionally is a so-called hard resin to be compatible with the desired optical qualities. Once the resin has been solidified, a converging lens 4 (generally, hemispherical) is arranged on the upper surface of the formed package. A diaphragm (not shown) may be interposed between package 10 and lens 4.

In FIG. 2, the network of microsensors of integrated circuit chip 1 has been shown with circles 11. In practice, the number of microsensors is much greater than the shown number, the integrated circuit chip having a surface area of a few square millimeters, and the number of phototransistors is, for example, on the order of 100,000 for a CIF-type sensor.

The selection of a hard resin 3 is linked on the one hand to the optical characteristics of these resins and on the other hand to the fact that the performed overmolding provides a sufficiently planar surface state (with intervals smaller than some forty micrometers) to place a glass converging lens 4.

The major disadvantage of an overmolding with a hard resin is that this generates stress on connecting wires 22 and generates a risk of bad contacts.

Another disadvantage of such a device is that it is limited in terms of focal distance. In particular, it does not enable addition of a lens separated from the upper surface of resin 3 by feet, due to the cumulated tolerances of the different added materials, which are incompatible with the absence of any adjustment (focus) of the focal distance.

### SUMMARY OF THE INVENTION

The present invention aims at providing a technique for encapsulating integrated circuits comprising optical microsensors, which overcomes the disadvantages of known package assemblies. In particular, the present invention aims at enabling assembly of different types of lenses on the package.

The present invention also aims at providing a solution compatible with the use of lenses with feet to increase the focal distance.

The present invention also aims at providing a solution compatible with wave soldering.

The present invention further aims at providing a solution which requires no modification in the forming of the actual microsensor integrated circuits.

To achieve these and other objects, the present invention provides an optical package for integrated circuit chips comprising optical microsensors, comprising, at least straight above the microsensors, an encapsulation resin having thickness smaller than the thickness provided straight above connecting wires extending between the upper surface of the chip and a substrate supporting it.

According to an embodiment of the present invention, a relatively thin resin thickness with respect to the thickness straight above the connecting wires is provided in areas for receiving feet of a focusing lens.

According to an embodiment of the present invention, the thickness of the resin above the microsensors is smaller than 200 μm, for example, smaller than 150 μm.

According to an embodiment of the present invention, the thickness of the resin above the connecting wires is at least 500 μm.

According to an embodiment of the present invention, the resin is a thixotropic resin.

The present invention also provides a method for forming an optical package for an integrated circuit chip in which optical microsensors have been formed and which is arranged on a substrate, connecting wires being welded between the upper surface of the chip and the substrate surface on which it rests, comprising depositing a thixotropic resin by replication, the thickness of the resin straight above the optical microsensors being smaller than the thickness of this resin straight above the connecting wires.

According to an embodiment of the present invention, a resin thickness smaller than the resin thickness straight above the connecting wires is also provided in areas of reception of a lens with feet.

The foregoing objects, features, and advantages of the present invention will be discussed in detail in the following non-limiting description of specific embodiments in connection with the accompanying drawings.

### BRIEF DESCRIPTION OF THE DRAWINGS

FIGS. 1 and 2, previously described, are intended to show the state of the art and the problem to solve;

FIGS. 3A, 3B, and 3C respectively show, in a simplified top view and in cross-section views along lines B-B′ and C-C′ of FIG. 3A, a preferred embodiment of an optical package according to the present invention;

FIGS. 4A, 4B, 4C, 4D and 4E illustrate in simplified cross-section views an embodiment of the optical package forming method according to the present invention;

FIG. 5 is a simplified cross-section view of a first variation of an optical device according to the present invention; and

FIG. 6 is a cross-section view of a second variation of such an optical device.

### DETAILED DESCRIPTION

For clarity, the same elements have been referred to with the same reference numerals in the different drawings and, as usual in the representation of integrated circuits, the various drawings are not drawn to scale. Further, only those elements and steps that are necessary to the understanding of the present invention have been shown in the drawings and will be described hereafter. In particular, the forming of the integrated circuit chip supporting the phototransistors forming the microsensor network has not been described in detail, the present invention being compatible with any conventional microsensor network. Further, the forming of the focusing lenses used by the present invention has not been described in detail either, the present invention being compatible with conventionally-formed lenses.

A feature of the present invention is to deposit a so-called replication resin on the integrated circuit supporting the microsensors resting on a substrate.

The resins deposited by replication are currently used in compact disk or digital video disk (DVD) forming techniques since they enable forming accurate patterns in the three dimensions X, Y, Z and especially in height (or thickness) even on large surface areas (large dimensions in X, Y).

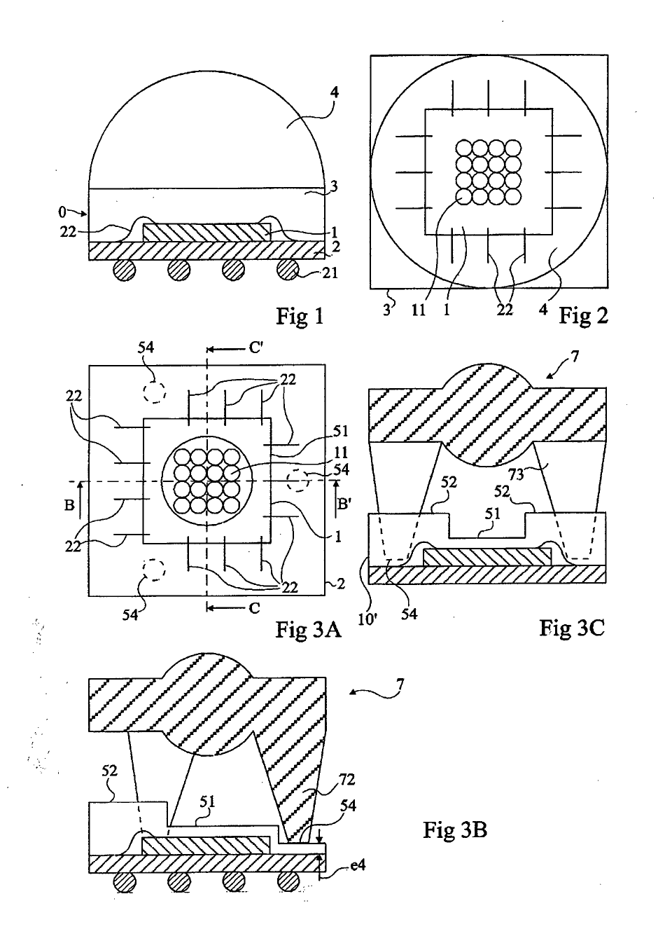

Briefly, a thixotropic resin is used, which becomes fluid when a slight pressure is applied thereto by means of a mold supporting the patterns to be formed. This mold is transparent to ultraviolet rays which are used to pre-polymerize the resin through the mold before it is definitively hardened by being passed through a furnace. Up to now, such resins deposited by replication are not used in electronic sensors (with a semiconductor chip) due to the required overmolding (typically greater than 500 μm) especially because of the connecting wires (22, FIGS. 1 and 2). With such thicknesses, these resins lose their quality of low tolerance in the formed pattern (especially, across the resin thickness) due to surface defects called “shrink marks” which appear for a thickness greater than approximately 200 μm.

According to the present invention, this resin deposition by replication is used with a specific mold pattern such that the resin thickness added on the central portion of the substrate (straight above the microsensors of the integrated circuit chip) is compatible with the absence of a shrink mark in the resin. Outside of this area, and more specifically straight above the connecting wires, the mold allows a deposition greater than 500 μm, and thus shrink marks. However, at this place, such optical defects are not disturbing.

This is a significant difference with respect to the conventional application of resins by replication in CD and DVD technologies where the absence of a shrink mark must be maintained in the entire surface of the optical disk.

Thus, the present invention takes advantage of the different features likely to be searched in the optical sensor surface to allow the presence or the absence of shrink marks according to locations.

According to a preferred embodiment, a small thickness is also provided in areas for receiving feet of focusing lenses to allow use of focusless lenses with feet. Indeed, given the small tolerance (smaller than 10 μm) of shallow surface defects of the replication resin, an optical device having a focal distance tolerance smaller than 40 μm is obtained for the complete device (taking into account the tolerances on the order of 10 or 20 μm above the feet of the focusing lens). For a focal distance of a few millimeters, such tolerances are compatible with the desired accuracy.

FIGS. 3A, 3B, and 3C show an optical device according to an embodiment of the present invention. FIG. 3A is a simplified top view. FIG. 3B is a cross-section view along line B-B′ of FIG. 3A. FIG. 3C is a cross-section view along line C-C′ of FIG. 3A.

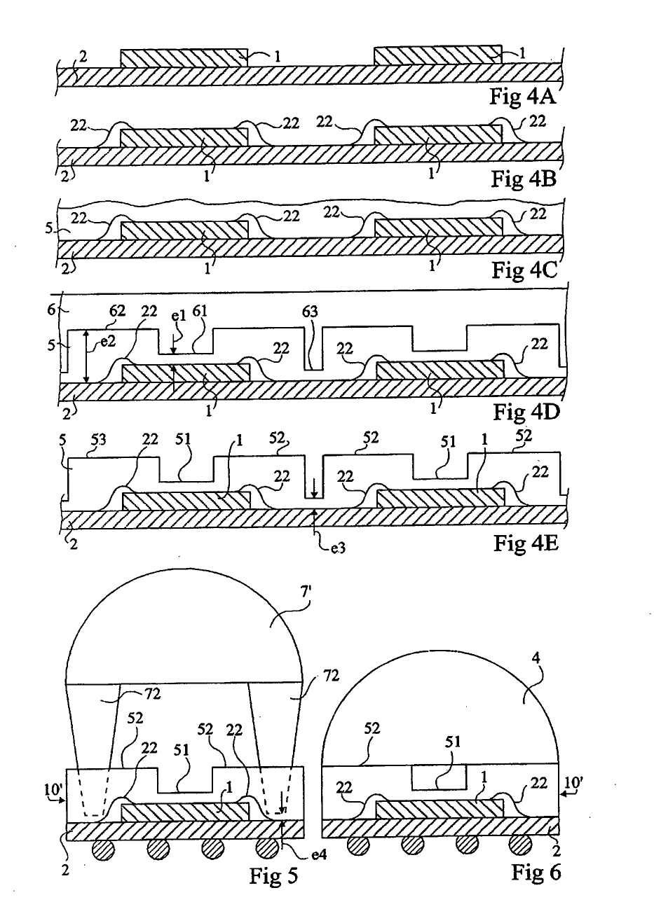

FIGS. 3A, 3B, and 3C will be described in relation with FIGS. 4A to 4E which illustrate an embodiment of the method for forming an optical package according to the present invention.

As previously (FIG. 4A), it is started from a substrate 2 on which are arranged integrated circuit chips 1 comprising the microsensors (11, FIG. 3A).

The contacts are then transferred (FIG. 4B) from the upper surface of chip 1 to the front surface of substrate 2 by means of conductive wires 22.

According to the present invention, a layer of thixotropic resin 5 of soft resin type with respect to the hard resins currently used to encapsulate the integrated circuits is then deposited (FIG. 4C).

Resin 5 is selected to have optical features adapted to the device to be formed. This belongs to conventional adjustments of these resins, especially to modify their optical indexes.

A mold 6 is then placed on the wafer supporting circuits 1. This mold comprises, in its surface opposite to the wafers, hollow pattern 62 and protruding patterns 61 and 63 such that at least resin thickness e1 remaining above the microsensor area is smaller than 200 μm (preferably, smaller than 150 μm). In FIG. 4D, mold 6 has been shown in its definitive position. It should however be noted that it is placed with a correct alignment in the plane. The slight pressure applied on this mold (with respect to the pressure necessary with conventional hard resins) liquefies resin 5 so that it easily fills mold 6, without imposing stress which would damage wires 22. The assembly is then submitted to ultraviolet rays to pre-polymerize (pre-harden) the resin. According to the present invention, resin thickness e2 above the connecting wires is of at least 500 μm.

Once the resin has been pre-polymerized, mold 6 is removed and the assembly is passed in a furnace to harden the resin. The collective structure shown in FIG. 4E is then obtained, in which the resin layer forming optical package 10′ exhibits thickness differences according to areas. In particular, areas 51 above the microsensors are of small thickness with respect to areas 52 above wires 22.

Preferably, a small resin thickness is also provided at the locations of the cutting paths. Thickness e3 conditioned by patterns 63 protruding from mold 6 is for example approximately 200 μm.

In the preferred embodiment of FIGS. 3, a small resin thickness e4 is also provided in areas 54 (FIGS. 3A and 3B) for receiving feet 72 (FIGS. 3B and 3C) of a lens with feet. This small thickness enables respecting the height tolerances for the positioning of the lens with feet to increase the focal distance of the optical devices.

In the example of FIGS. 3A, 3B, and 3C, the lens has a small BFL (back focal lens) with a focal distance set by the distance between the focal point and one of the physical bearing points.

It should be noted that the fact the small resin thickness e1 is recessed with respect to the relatively thick peripheral contour enables protecting this area of the optical sensor during the wafer handling (FIG. 4E) before its cutting.

The final assembly of the focusing lens is performed by gluing the feet thereof on the provided reception areas. Then, the assembly is directly assembled on a printed reception circuit linked to the application.

An advantage of the present invention is that it enables avoiding risks of breakage of the connecting wires on encapsulation of the optical structure.

Another advantage of the present invention is that it enables use of lenses with feet, and thus allows increasing of the focal distance.

Another advantage of the present invention is that it enables wave soldering of the circuits thus formed.

FIG. 5 shows a first variation in which a lens with feet is a hemispherical lens 7′. The same method comprising providing small resin thicknesses e4 above feet 72 of the lens is then used. Preferably, although the invention is not so limited, the number of feet of lenses with feet is 3.

FIG. 6 shows a second simplified variation of the present invention. In this variation, a hemispherical lens 4 is arranged directly on optical package 10′ resulting from the implementation of the present invention. As compared with the conventional forming of FIG. 1, the advantages which remain in this embodiment are the use of a resin deposited by replication, which limits the stress applied to the wires on overmolding. However, this does not enable increasing the focal distance with a lens with feet.

Of course, the present invention is likely to have various alterations, modifications, and improvements which will readily occur to those skilled in the art. In particular, the selection of the resin to be used is within the abilities of those skilled in the art according to the application.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. An optical package for integrated circuit chips comprising optical microsensors, comprising at least straight above the microsensors, an encapsulation resin having thickness smaller than the thickness provided straight above connecting wires extending between the upper surface of the chip and a substrate supporting it.

2. The package of claim 1, wherein a relatively thin resin thickness with respect to the thickness straight above the connecting wires is provided in areas for receiving feet of a focusing lens.

3. The package of claim 1, wherein the thickness of the resin above the microsensors is smaller than 200 μm, for example, smaller than 150 μm.

4. The package of claim 1, wherein the thickness of the resin above the connecting wires is at least 500 μm.

5. The package of claim 1, wherein the resin is a thixotropic resin.

6. A method for forming an optical package for an integrated circuit chip in which optical microsensors have been formed and which is arranged on a substrate, connecting wires being welded between the upper surface of the chip and the substrate surface on which it rests, comprising depositing a thixotropic resin by replication, the thickness of the resin straight above the optical microsensors being smaller than the thickness of this resin straight above the connecting wires.

7. The method of claim 6, wherein a resin thickness smaller than the resin thickness straight above the connecting wires is also provided in areas of reception of a lens with feet.
